(19) United States
(12) Patent Application Publication
(10) Pub. No.: US 2006/0014083 A1
(43) Pub. Date: Jan. 19, 2006

(54) Methods and systems for fabricating electronic and/or microfluidic structures on elastomeric substrates

(75) Inventor: Robert Carlson, Seattle, WA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: University of Washington, Seattle, WA (US)

(21) Appl. No.: 11/070,028

(22) Filed: Mar. 1, 2005

Related U.S. Application Data
(60) Provisional application No. 60/549,298, filed on Mar. 1, 2004.

(51) Int. Cl. G03F 1/00; G03G 17/04

(52) U.S. Cl. 430/5; 310/309; 356/145; 430/33

(57) ABSTRACT

The present invention provides methods and systems for fabricating electronic and/or microfluidic structures on elastomeric substrates. In one method, a protective structure is positioned onto a portion of a surface of the hydrophobic substrate. An unprotected portion of the surface is activated to become hydrophilic, wherein the protected portion of the surface of the substrate remains hydrophobic. The protective structure is removed from the surface of the substrate and material is deposited on the hydrophobic portion to form a structure on the substrate.

### CROSS-REFERENCES TO RELATED APPLICATIONS

The present application claims benefit to U.S. Provisional Application Ser. No. 60/549,298, filed Mar. 1, 2004, entitled “Methods for Fabricating Self-Assembled Optical and Electronic Structures on Silicone Rubber,” the complete disclosure of which is incorporated herein by reference.

### STATEMENT AS TO RIGHTS TO INVENTIONS MADE UNDER FEDERALLY SPONSORED RESEARCH OR DEVELOPMENT

This work was supported in part by grant number 5 RO1 HG001497-07 from the National Institutes of Health. The U.S. Government may have certain rights in the invention.

### BACKGROUND OF THE INVENTION

The present invention relates generally to methods for fabricating integrated electromechanical devices, microfluidic devices, and optical devices. More specifically, the present invention is directed toward methods of self-assembling conductive structures on a poly(dimethylsiloxane) (PDMS) substrate.

It has long been desired to have microfabrication techniques that enable construction of integrated electromechanical devices for such things as reagent handling, temperature control, and pumping. Commercially available microfluidic devices are predominantly fabricated in relatively expensive materials, such as silicon and glass. However, due to cost limitations, the use of silicon and glass based devices has been limited. In addition, while there is considerable experience in building devices with these materials, which allows inclusion of complex functionality on a chip, they are problematic even for laboratory use due to extensive and expensive fabrication processes.

Another material that has been used in microfabrication of such devices is silicone elastomer, and in particular PDMS. Because PDMS is biocompatible and inexpensive, use of PDMS could decrease the costs of manufacturing integrated electromechanical and microfluidic devices. Unfortunately, similar to the methods of microfabricating silicon and glass, current methods of depositing metal on PDMS also are often carried out with an expensive vapor deposition apparatus. Additionally, because vapor deposition of the metal occurs at high temperatures, the high temperatures tend to distort the PDMS substrate and often renders the PDMS substrate unusable.

Consequently, what are needed are improved methods of fabricating electronic structures on a silicone rubber substrate. It would be desirable if such methods were performed at lower temperatures so as to not distort or otherwise damage the silicone rubber substrate.

### BRIEF SUMMARY OF THE INVENTION

The present invention provides low cost methods of fabricating electromechanical and microfluidic devices. The methods of the present invention provide a self assembly process that is carried out at temperatures significantly below conventional manufacturing processes (e.g., room temperature).

The present invention provides methods of fabricating complex patterns of active and non-active components on an elastomeric substrate, such as PDMS. The creation of the complex patterns on PDMS is carried out using simple fabrication methods that “activate” selected portions of the PDMS substrate so as to take advantage of the changing hydrophobic and hydrophilic nature of the elastomeric substrate and/or the changing chemical properties (e.g., oxidation state) of the catalyst (or additives) in the elastomeric substrate when portions of the substrate are activated.

Plasma treatment or acid treatment of silicone rubber causes the normally hydrophobic silicone rubber to become hydrophilic. Thus, by applying the plasma treatment or acid treatment (e.g., “activating) to only a portion of the silicone rubber, the methods of the present invention are able to provide a partially hydrophobic and partially hydrophilic silicone rubber substrate. By creating a desired pattern of the hydrophobic portion of the substrate, the present invention is able to selectively create a customized pattern for the material/structure that is to be deposited on the silicone rubber substrate. Applicant has been able to pattern a variety of different structures onto the PDMS structure using a chemical deposition process, hydrophobic patterning, or self-assembly.

To create the hydrophobic/hydrophilic patterns on the silicone rubber substrate, a patterned protective structure may be placed over the selected portion(s) of the surface of the silicone rubber so as to prevent the plasma or acid from contacting the selected portion(s). Preventing contact of the plasma or acid with the selected portion(s) allows the portion(s) of the silicone rubber substrate to maintain its hydrophobic nature. Whereas the portions of the silicone rubber substrate that are exposed to the plasma or acid becomes hydrophilic.

The patterned protective structure can take a variety of forms, but it is typically in the form of a customized PDMS/silicone rubber pad that is patterned in a shape that corresponds to the desired shape of the conductive structure that is to be formed on the silicone rubber substrate. The protective structure is sealed against the surface of the silicone rubber substrate. Alternatively, the protective structure may be a pattern of photoresist that is temporarily applied onto selected portions of the silicone rubber substrate, a Mylar stencil, metal foil, plastic sheeting, glass mask, a silicon mask, or the like.

A variety of different materials may be patterned onto the silicone rubber substrate. For example, patterns of conductive materials (e.g., gold, silver, copper, graphite powder, zinc oxide, iron oxide, semiconductor powders-doped silicon, and other conductive optically opaque powders), non-conductive materials (e.g., optically opaque or optically clear), or any combination thereof, have been patterned on the surface of the silicone rubber substrate. Such materials have been used to fabricate components such as wires, inductor cores, resistors, capacitors, electrostatically-actuated valves, heaters, pumps, magnetic elements, and the like.

Advantageously, the methods and devices of the present invention are flexible enough to enable transferring and stacking of individual silicone rubber substrates that contain any of the above components. Consequently, the present invention is able to construct complex, multi-layer composite devices, either by building layer-on-layer or by combining a plurality of individually fabricated layers.

For example, in one embodiment, the present invention provides a multi-layer electrostatic actuator. The electrostatic actuator of the present invention is composed of a plurality of layers of PDMS and comprises a plurality of flexible and extensible electrodes.

The electrostatic valve comprises a first and second crossed channels that are separated by a first flexible electrode. A second electrode is positioned on an opposed side of second channel. When no voltage is applied across the first electrode and the second electrode, fluid is allowed to flow through the second channel. Application of a voltage across the flexible, first electrode and the second electrode (typically between about 100 Volts and about 600 Volts, and preferably about 200 Volts) causes the flexible first electrode to flex or otherwise bow into the second channel toward the second electrode to reduce (e.g., stop) fluid flow through the second channel.

The valves of the present invention often comprise electrodes that are comprised of an carbon powder (e.g., graphite) that is embedded in a PDMS membrane, forming an extensible (e.g. stretchable) electrode. Because the carbon powder granules are able to move relative to each other during the two-dimensional stretching (while still being able to maintain electrical contact with each other), such electrodes are flexible and in testing have not demonstrated mechanical failure. Yet another preferred electrode configuration is a composite of gold and graphite powder. In such embodiments, the gold is chemically deposited between the graphite granules. Such electrodes provide the flexibility of the graphite powder electrode, while providing the improved conductivity of a gold electrode.

In another embodiment, the present invention also provides an electrostatic actuator or pump that is formed by combining a plurality of PDMS-based layers in which at least some of the layers contain components that have conductive leads and/or electrodes.

The pump typically provides a series of valves that pressurizes a working fluid in a first channel, which effectively creates a bellows, which then compresses a membrane beneath a second channel that contains a sample fluid. Delivery of a voltage across a first and second electrode in the pump causes the first electrode to flex toward the second electrode. At least a portion of the first channel may be disposed between overlapped portions of the first and second electrodes such that when the first electrode flexes into the first channel toward the second electrode, the first electrode causes a pressurization of the working fluid in the first channel.

The pressurization of the working fluid causes a pressurization of the membrane around the first channel and forces the working fluid membrane into the second channel (e.g., sample channel). The pressurization of the working fluid membrane causes the second channel to be closed off. Removal of the voltage between the first and second electrodes causes the first electrode to return to its straight configuration. Consequently, the pressurization of the first channel and second channel will be removed and the sample fluid is allowed to continue to flow through the second channel.

In another aspect, the present invention provides photolithographic masks and methods of manufacturing the photolithographic mask. Such methods utilize the same steps described herein to self-assemble an optically opaque material onto selected portions (e.g., protected, hydrophobic portions) of a silicone rubber substrate. Once the optically opaque material has been self assembled onto the silicone rubber substrate, it may be possible to apply another layer of liquid silicone rubber to encapsulate and protect the optically opaque material. If desired, it is possible to stack a plurality of single layer photolithographic masks to fabricate a more complex mask pattern or to control the optical properties of the composite material.

In an alternative embodiment, the photolithographic masks may be fabricated by mixing an optically opaque powder (or liquid) into liquid silicone rubber or other curable solution. Thereafter, the liquid silicone rubber may be deposited into custom patterned channels that are formed in a clear substrate (e.g., clear PDMS). Thereafter, the liquid silicone may be cured inside the channels to form the photolithographic mask.

Optionally, the photolithographic masks of the present invention may be cut and reassembled to make customized larger or smaller masks, i.e., mosaic photolithographic mask or movable type photolithographic mask. In order to reassemble the masks into a desired pattern, one only needs to press the edges of the smaller sections of the mask together to optically seal the sections to each other.

The above aspects and other aspects of the present invention may be more fully understood from the following detailed description, taken together with the accompanying drawings.

### BRIEF DESCRIPTION OF THE DRAWINGS

FIG. 1 illustrates one exemplary method of activating a surface of an elastomer substrate and depositing material on the elastomer substrate.

FIG. 2 illustrates self-assembled gold electrode leads formed on a PDMS substrate.

FIG. 3 illustrates a self assembling method of forming structures on an elastomer substrate using a chemical deposition process.

FIGS. 3A and 3B are photographs of two gold wires on a ˜20 micron thick PDMS substrate, on a thicker flexible backing material, that was manufactured by the method of FIG. 3.

FIG. 4 illustrates a method of applying a conductive powder onto a hydrophobic/protected portion of a PDMS substrate.

FIG. 5 illustrates a powder-based lead pattern that is formed on a surface of a silane treated PDMS substrate.

FIG. 6 is a photo of a graphite pattern that is formed by the method of FIG. 5.

FIG. 7 is a trimmed PDMS substrate of FIG. 6 that is mounted on a glass wafer.

FIG. 8 illustrates a contact lithography and projection lithography assembly.

FIG. 9 illustrates a moveable photomask encompassed by the present invention.

FIG. 10 illustrates two separate photoresist structures made using the reassembled mask of FIG. 9.

FIG. 11 is an exploded view of a multi-layered assembly that may be fabricated using the methods of the present invention.

FIG. 12 is a photo of a completed five layer pump that is encompassed by the present invention.

FIG. 13 illustrates one method of creating electrical connections to a conductive structure embedded in a PDMS substrate.

FIG. 14 illustrates another method of creating electrical connections to a conductive structured embedded in a PDMS substrate.

FIG. 15A illustrates an open electrostatic actuator/valve composed of a first and second electrode, in which the first electrode separates a first and second channel and a top view photograph of the open valve.

FIG. 15B illustrates the electrostatic actuator/valve with a voltage across the first and second electrode which causes the first electrode to flex into the second channel to close the second fluid channel and a top view photograph of the closed valve.

FIG. 16A is a side view schematic of an electrostatic actuator that comprises three valves that work together to create a peristaltic pump.

FIG. 16B is a side view schematic of the electrostatic actuator of FIG. 16A that is displacing a working fluid that in turn compresses a membrane up into a sample channel.

FIG. 16C is a top-down photo of a prototype peristaltic pump encompassed by the present invention.

FIG. 17 illustrates a fabrication method of the electrostatic actuator of FIGS. 16A to 16C.

### DETAILED DESCRIPTION OF THE INVENTION

The present invention provides methods and systems for self-assembling structures (e.g., conductive or non-conductive) onto a substrate. Methods of the present invention generally include activating or otherwise altering the chemical properties of selected portions of the substrate. Typically, the portions that are not activated or altered are protected with a patterned protective structure. Thereafter, a material is deposited (e.g., self-assembled) onto either the activated or non-activated surface of the substrate.

The methods of the present invention enable construction of integrated electromechanical devices and microfluidic devices for such things as reagent handling, temperature control, pumping. Some specific devices that may be fabricated using the methods of the present invention include, but are not limited to, flexible computer displays, electrostatic actuators used in valves and peristaltic pumps. As can be appreciated, while not specifically listed, the present invention may be used for producing any number of other polymer-based device that contain active or inactive components.

The material deposited on the substrate may be patterned and shaped to fabricate a variety of different components, such as wires/leads, resistors, capacitors, electrostatically-actuated valves, magnetic elements, heaters, optical structures and components, or the like. The deposited material itself may be a conductive structure that comprises one or more of gold, copper, silver, a powder (e.g., graphite, zinc oxide, iron oxide, semiconductor powder, etc.), any optically opaque material, other conductive liquids or powders, or non-conductive optically opaque (or optically clear) materials. In one particularly preferred embodiment, the deposited material comprises a gold layer that intercalates in a graphite/carbon powder. Such a material has been found to be flexible, while providing improved conductivity.

As used herein, the term “activated” or “activation” is used to include any conventional or proprietary process which either (1) changes an hydrophobic substrate to a hydrophilic substrate (or vice versa), or (2) causes a change in the activity of a catalyst or other component of the substrate, so that only one of the activated and un-activated portions of the substrate will be able to interact/bond with the material that is to be deposited on the surface. Some preferred methods of activating the substrate include plasma or acid treatment.

The substrates of the present invention are typically in the form of a flexible elastomeric substrate. Some useful elastomeric substrates include a silicone rubber, silicon, plastic, or the like. Additionally, while flexible elastomeric substrates are preferred embodiments, a variety of other dielectric materials having different properties may be used as the substrate. For example, the substrate may be any plastic that comprises a catalyst that can be adapted (through activation) to interact with the material that is deposited on the surface.

The substrates of the present invention may be any material that can be modified from a hydrophobic material to a hydrophilic material, or vice versa. Alternatively, the substrate may be any material that includes an additive that is adaptable through activation to interact or not interact with the material that is to be deposited on the surface of the substrate. For example, an additive that is activatable through the plasma treatment (for example, platinum, or another material used as a catalyst) may be added to a plastic substrate to allow for forming of a conductive structure on the plastic substrate. As long as the additive doesn't affect the curing of the substrate, any number of conventional or proprietary additives may be added into the substrate. In such embodiments, the substrate will not have to have a catalyst whose properties are changeable (e.g., platinum catalyst in PDMS).

One particularly useful substrate embodied by the present invention is a hydrophilic poly(dimethylsiloxane) (PDMS) substrate. PDMS is hydrophobic and is composed of a silicone monomer, in many formulations containing a catylst, often platinum, and a platinum based catalyst. As will be described in more detail below, some methods of the present invention are able to deposit a material onto the substrate by taking advantage of the fact that activation of the hydrophobic surface of the PDMS will change the PDMS into a hydrophilic material, while other methods of the present invention deposit the material on the substrate by taking advantage of the chemical changes, property changes, and/or alteration of the oxidation state of the platinum catalyst during the activation.

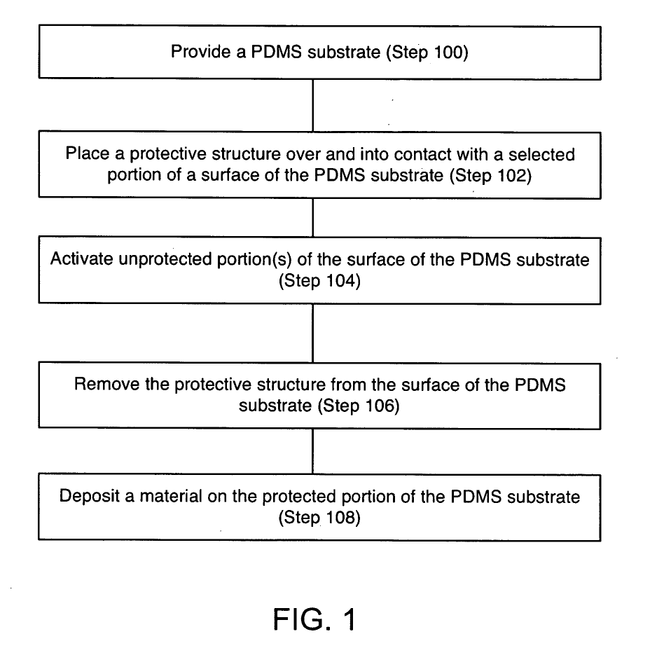

FIG. 1 illustrates a simplified method of forming a conductive structure on a PDMS substrate. While the remaining discussion of FIG. 1 focuses on self-assembling a conductive material (e.g., gold) on a PDMS substrate, it should be appreciated that any of the aforementioned substrates and materials described herein are applicable to the method of FIG. 1.

A PDMS substrate is provided by mounting a thin layer of PDMS to a glass wafer or slide (Step 100). The PDMS substrate may be any thickness but is typically between 1 micron and 1 cm thick. A protective structure is placed over and into contact with a portion of a surface of the PDMS substrate that is to be “protected” (Step 102). The protective structure may be any structure that is able to contact and seal against the surface of the PDMS substrate to prevent the activating agent from contacting the portion of the surface that is to be protected. The protective structure will comprise one or more elements to form a protected pattern on the surface of the PDMS substrate. Typically, the protective structure will be in the shape of one or more leads or electrodes. In exemplary embodiments, the protective structure may be in the form of one or more PDMS stamps, a photolithographically patterned photoresist, or the like.

One challenge in patterning photoresist on PDMS is that a surface of the PDMS is not easily wet by many photoresist. For example, AZ 1512, (manufactured by Microchemicals, GMBH) which is a common negative photoresist, does not form a stable film on a hydrophobic PDMS surface. Presumably, this is due to the polar solvents in the photoresist. One photoresist which has been found to be adhere o an untreated surface of PDMS is SIPR-7120 Series by Shin-Etsu MicroSi, Inc. of Phoenix, Ariz. A stable thin film of between 1 and 30 microns has been spun onto the surface of the PDMS. The SIPR-7120 photoresist protects the surface of the PDMS substrate from being activated during the “activation.”

After the protective structure has been positioned on the surface of the PDMS substrate, an activation agent is applied to the surface of the PDMS surface to activate the substrate (Step 104). As noted above, activation of the PDMS surface is typically carried out with a plasma or acid treatment. Typically, the activation treatment will last approximately five minutes, but may be more or less depending on the particular activating agent used.

Plasma or acid treatment of a normally hydrophobic silicone rubber (PDMS) causes the silicone rubber to become hydrophilic. While the exact activation mechanism isn't fully understood, the activation of the surface has proven to be useful to provide for adhesion of the conductive material onto the hydrophobic portion of the surface, while preventing bonding of the conductive material to the activated, hydrophilic portion of the surface.

After the plasma or acid treatment has activated the non-protected portions of the PDMS surface the protective structure can be removed from the surface of the PDMS substrate so as to expose the protected, and thus hydrophobic portions of the PDMS surface (Step 106).

After the protective structure has been removed, the material may be deposited onto the hydrophobic portions of the PDMS substrate (Step 108). In one preferred embodiment, gold is deposited onto the hydrophobic portions of the PDMS substrate in a chemical deposition process. In such embodiments, an electroless process is used to deposit the gold on the PDMS surface. The reaction typically uses a gold toning agent (e.g., gold chloride) and an autocatalytic reduction of gold occurs from the source (gold chloride) with an electron donor such as hydroquinone or potassium cyanide. The gold from the gold source interacts with the platinum catalyst in the protected/hydrophobic portion of the PDMS substrate, but not with the platinum catalyst in the unprotected/hydrophilic portion of the PDMS substrate. While the exact chemical mechanism responsible as to why gold is deposited only on the hydrophobic portions of the PDMS substrate is unclear, Applicant believes that it is due to one or both of the following, (1) activation of the surface through plasma treatment creates a glassy silica barrier that prevents reaction of the platinum catalyst with the gold solution, and/or (2) activation of the surface through plasma treatment changes the oxidation state of the platinum, thus suppressing the gold deposition reaction.

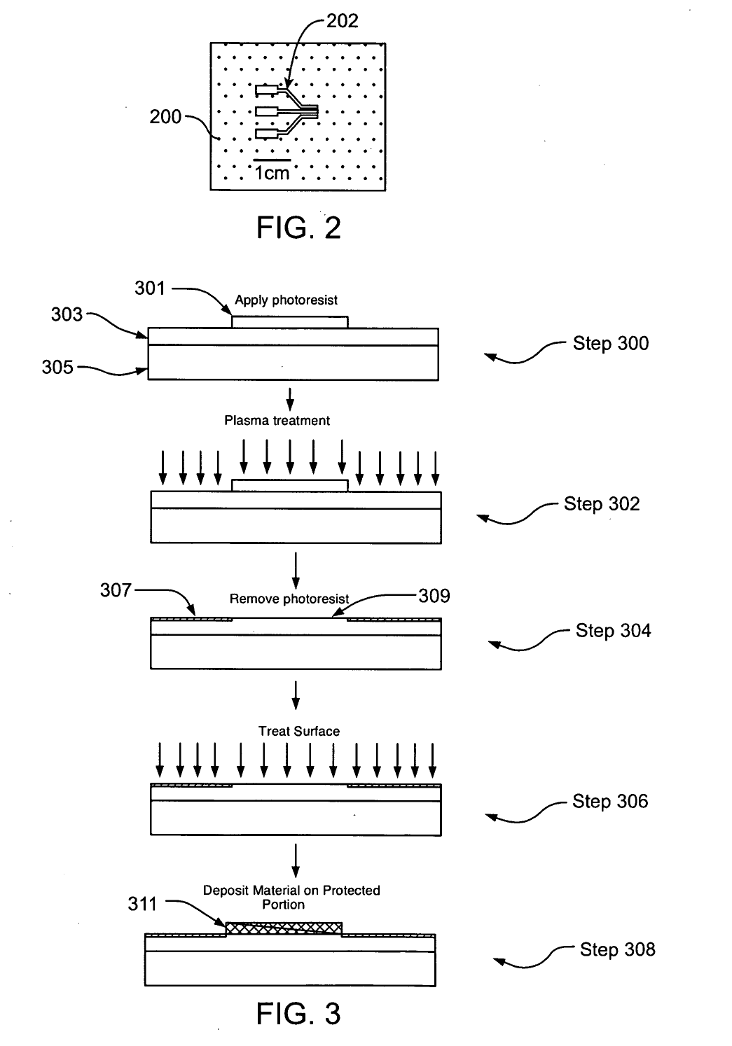

FIG. 2 illustrates a prototype PDMS substrate 200 that comprises a plurality of flexible gold electrode leads 202 that are self-assembled at room temperature via the aforementioned electroless deposition process. In the illustrated embodiment, the PDMS substrate 200 is approximately 25 microns thick and the gold electrode leads 202 have a width between about 500 and about 2000 microns and a height between about 0.05 microns and about 0.1 microns. Depending on their size and volume, the electrodes can have resistance from sub-ohm to a mega-ohm. Unlike the conventional methods, which vapor deposits a conductive material on the substrate at high temperatures, the electroless deposition methods of the present invention are significantly less expensive than vapor deposition and occur at room temperature, thus avoiding deformation and damage to the underlying elastomer substrate. Advantageously, unlike thermal evaporation, which covers the entire inside of an evaporation chamber with metal, metal is deposited only where it is desired on the substrate.

As can be appreciated, the width of the electrodes may be modified merely by increasing or decreasing the size of the hydrophobic portions on the PDMS substrate, while the height or thickness of the conductive material may be modified by altering the length (time) of the deposition.

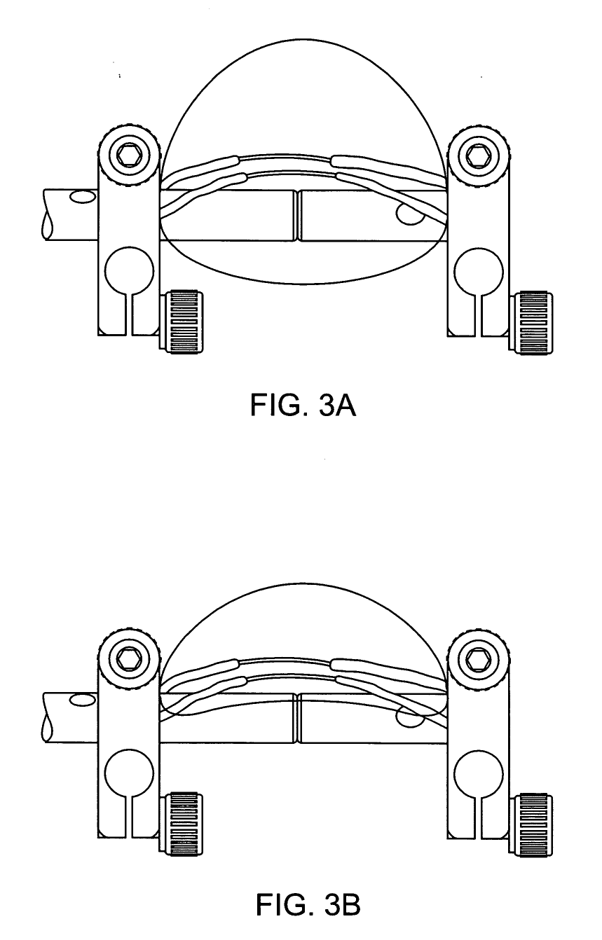

FIG. 3 illustrates a specific embodiment of the present invention in which the protective structure is in the form of photolithographic photoresist. At step 300, the photoresist 301 is patterned in a desired pattern over a surface of the PDMS substrate 303 (which is mounted on a glass wafer or slide 305), typically by spin coating the photoresist onto the substrate. The spin coated photoresist is baked in an extended low temperature bake at approximately 60° C. for about 2 hours to remove solvents from the photoresist that have entered the PDMS substrate. The photoresist may then be exposed to UV light through a mask. Any photoresist that is exposed to the UV light is removed using a conventional developing solution. After the desired photoresist pattern is placed on the PDMS substrate, the photoresist pattern may optionally be exposed to UV light and heated to ease the removal of the photoresist after the plasma treatment. Of course, while not described herein, a conventional negative resist may also be used with the methods of the present invention to achieve similar results.

The PDMS surface with the photoresist pattern is then exposed to a plasma for a time sufficient to activate the exposed surface of the PDMS (Step 302). Typically, the PDMS surface and photoresist pattern are exposed to the plasma for approximately 5 minutes, but it could be more or less depending on depending on the size of the features being patterned. For example, the pattern is typically created within 30 seconds (to create the hydrophilic patterns and to cause an oxidation state change), but depending on the pattern formed, could take between about 5 minutes and about 30 minutes. The photoresist is then removed from the surface of the PDMS substrate by dissolving it with acetone (Step 304). As shown by the cross-hatched sections 307 in FIG. 3, the unprotected portions of the PDMS surface that was exposed to the plasma will be hydrophilic, and the portion(s) 309 that were protected by the photoresist will remain hydrophobic.

Thereafter, the surface of the PDMS substrate may then be treated to prepare it for deposition of the material (Step 306). For example, the PDMS surface may be immediately rinsed with isopropyl alcohol (IPA). Immediately following the IPA rinsing, the surface may be rinsed with de-ionized (DI) water. Because IPA is soluble in PDMS, the IPA rinse results in loading the rubber with IPA. Thorough removal of the IPA from the PDMS may be accomplished with the extended rinse in the DI water, typically via submersion. Finally, the rinsed surface of the PDMS is dried to maintain the hydrophobic/hydrophilic pattern. Applicant has found that it is desirable to gently dry the rinsed surface of the PDMS substrate so as to maintain and not damage the hydrophobic/hydrophilic pattern. One useful method of gentle drying is spin drying on a thin film spinner. Applicant has found that vigorous direct drying with a nitrogen, atmospheric or compressed gas steam may destroy the pattern formed on the surface of the PDMS. After treating the surface of the PDMS substrate, using the methods described above, the gold (or other desired material) 311 may be deposited onto the portion(s) 309 of the PDMS substrate that was protected by the photoresist (Step 308).

FIGS. 3A and 3B are photographs of two chemically deposited gold wires on a silicone rubber (PDMS) substrate. Silver paint leads are coupled to the ends of the deposited gold wires on each end. The PDMS substrate is ˜20 microns thick and was spun onto a “printer transparency.” The gold wires were deposited onto the PDMS substrate using the method described in relation to FIGS. 1 to 3. The gold wires are very flexible and are suitable for use in a flexible computer display, handheld device display, or an eBook device.

In addition to allowing self assembly of conductive structures on the PDMS substrate through an electroless deposition process, the methods of the present invention are able to self assemble materials onto a surface of the PDMS substrate using other methods. While Applicant believes that the methods of FIGS. 1-3 take advantage of the chemistry change of the platinum catalyst to deposit the gold material in a pattern on the PDMS substrate, the methods of the present invention are also able to take advantage of the hydrophobic/hydrophilic portions of the surface of the PDMS substrate.

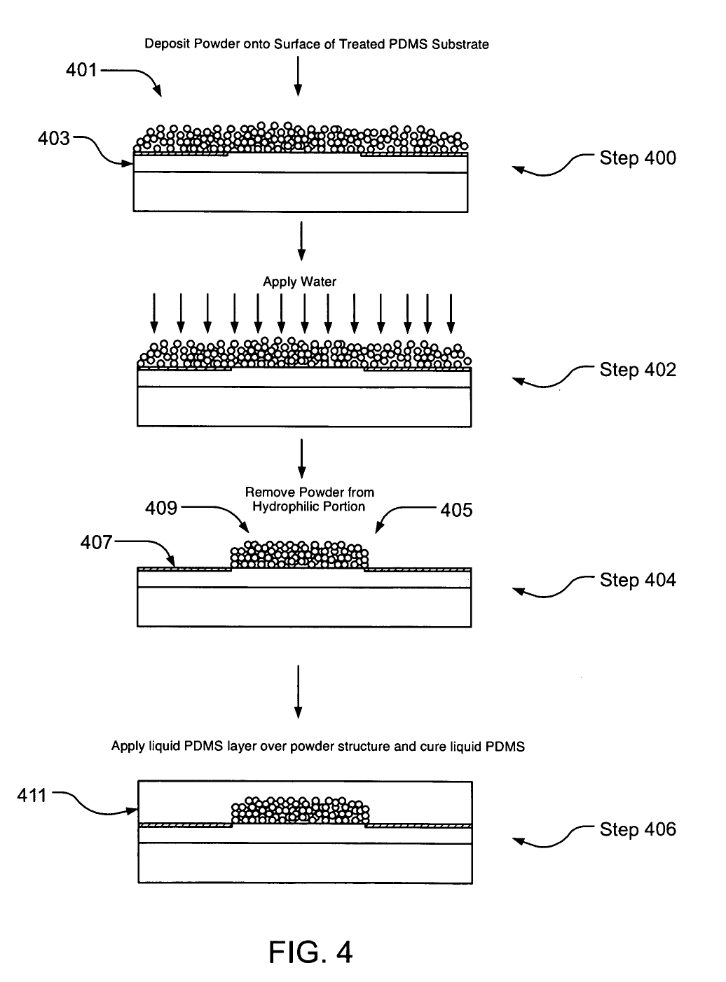

For example, FIG. 4 illustrates one method of the present invention that is able to self-assemble a number of different powders, such as graphite, iron oxide, zinc oxide, and semiconductor powders, onto the surface of the PDMS substrate using a water bath.

As shown in FIG. 4, after processing the PDMS substrate (or other hydrophobic substrate) to produce the hydrophilic/hydrophobic patterns (as described above and shown in FIG. 1), a desired powder 401 is applied onto the dry surface of the PDMS substrate 403 (Step 400). Applicants believe that smaller granule powders are preferred, over larger granule powders. Moreover, it may be possible to pre-treat the granules of the powder so that they are hydrophobic, which would enhance their tendency to assemble on the hydrophobic area of the substrate. Typically, the powder is gently rubbed onto the dry surface so that the powder adheres to the entire surface. However, for a larger scale of manufacture, an automated roller or sonication may be used to adhere the powder to the hydrophobic portion of the substrate. Optionally, it may be desirable to pre-wet the substrate so that the water prevents the deposition of the powder all together on the hydrophilic portions of the substrate.

After the powder is applied, water (or additional water) may then applied to the surface of the PDMS (Step 402) In the presence of the water, in the hydrophobic portions 405 the powder sticks to the PDMS substrate. In the hydrophilic portion 407 of the PDMS substrate, water is drawn to the PDMS substrate and the powder 401 is easily removable from the hydrophilic areas 407. Consequently, with gentle rubbing or other agitation of the powder on the surface of the PDMS substrate 403, the powder 401 can be easily removed from the hydrophilic/unprotected portion 407 of the PDMS substrate, thus leaving the powder only on the hydrophobic portion 405 (Step 404). The resultant structures 409 can serve as wires, inductor cores, electrodes, semiconductor structures, optical structures, or other electronic components.

The powder based structures formed on the hydrophobic portions of the PDMS substrate can be maintained on its particular location on the substrate/device or the powder structure can be picked up and moved onto another substrate. As shown in FIG. 4, the resultant structure 409 is extends beyond the plane of the top surface of the PDMS substrate 403 and may easily be disturbed, unless otherwise protected. One method of removing/protecting the powder based structure is shown in as an optional step 406 in FIG. 4 and comprises applying and a liquid layer of PDMS (or other liquid elastomer) 411. A thick layer of liquid PDMS may be applied or a thin liquid layer of PDMS may be spun on. Thereafter, the additional layer of PDMS is cured on top of the powder based structure. The liquid PDMS intercalates into the powder upon curing and the powdered structure is therein incorporated into the cured PDMS layer. Advantageously, intercalation creates a stable structure that is robust to mechanical perturbation (e.g., can be bent, stretched without breakage). Moreover, the bottom layer of PDMS serves as an insulator for the electrode where the electrodes passes into a fluid-filled channel. Such an insulator will allow a capacitive connection to fluid but does not allow an ohmic connection (e.g., direct contact).

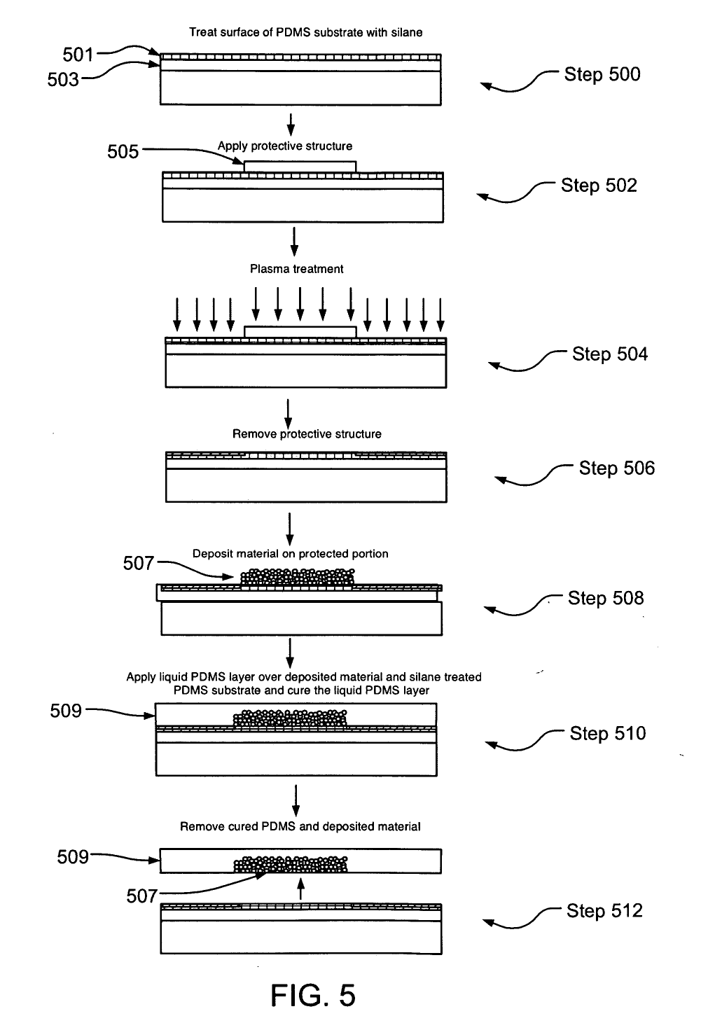

FIG. 5 illustrates another embodiment of the present invention in which, the primary difference from the method of FIG. 4 is the use of a silane treated PDMS substrate. In such embodiments, the surface of the PDMS substrate 503 in which the powder substrate is to be formed is first treated with silane 501 or other similar agents which may prevent adherence of other PDMS layers (or other elastomer layers) to the PDMS substrate (Step 500). The patterned protective structure 505 (e.g., PDMS stamp, photoresist, etc.) is positioned on the surface of the PDMS structure 503 to be activated (Step 502) and the silane treated PDMS surface is activated (Step 504). The protective structure is removed (Step 506) and the material is self-assembled or otherwise deposited onto the hydrophobic/protected portion of the surface of the PDMS substrate according to any of the aforementioned methods (Step 508). In one preferred embodiment, graphite powder is added to the hydrophobic areas of the PDMS substrate. Because the graphite pattern 507 is on a silanized PDMS substrate, the graphite powder is in the form of a free standing structure that can be picked up and moved. In one method of moving the graphite structure, liquid PDMS is poured over the graphite pattern and then the liquid PDMS 509 is cured (Step 510). The cured PDMS layer may then be removed from the silanized PDMS substrate, thus taking the graphite pattern 507 along with it (Step 512).

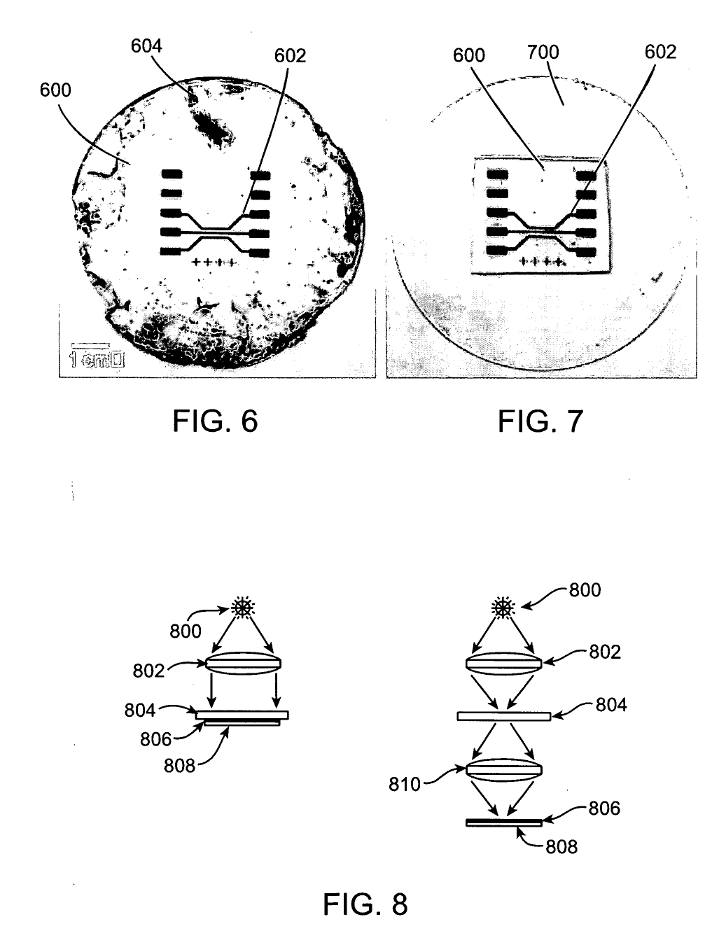

The resultant structure provides a conductive graphite pattern that is encapsulated by the cured PDMS layer, in which a bottom surface of the PDMS 509 is along a same plane as the bottom surface of the graphite pattern 507. FIGS. 6 and 7 illustrate one embodiment of a graphite lead pattern 602 that is formed using the method illustrated in FIG. 5. The background adhesion 604 seen on the edges of the PDMS substrate 600 was due to incomplete removal of photoresist protective structure before plasma treatment. In embodiments which use a patterned PDMS pad as the protective structure, such background adhesion would not be present. FIG. 7 shows the PDMS substrate 600 of FIG. 7 mounted on a glass wafer 700, in which the dirty edges have been trimmed, thus leaving a clean, opaque graphite pattern 602 in the PDMS substrate 600.

As can be appreciated, the methods of the present invention are not limited to silane treated PDMS layers and other materials other than silane may be used with the present invention to prevent adhesion between the different PDMS layers. For example, Applicant has found that monolayers of detergent, deposited by drying soapy water on substrate may also be useful in preventing adherence between the PDMS layers.

In another aspect, the present invention provides photolithography masks and methods of fabricating the photolithography masks. As shown in FIG. 8, current photolithographic techniques for patterning the exposure of photoresist require a light 800 source and optical assembly 802, a mask 804 that is in contact with the photoresist 806 and substrate 808 (silicon wafer, PDMS membrane, etc.) (contact photolithography), or the photolithographic techniques utilize an optical/projection system 810 (projection photolithography), where the mask 804 may be a large distance from the photoresist 806 and substrate 808. Inexpensive contact photomasks can be produced with laser printers for low resolution work (e.g., down to ˜10 microns), while high resolution photolithography is typically carried out with chrome-on-quartz masks that can cost a thousand dollars, or more. Unfortunately, the chrome masks are easily damaged when used in contact photolithography, and for high resolution work, the scratches in the chrome can easily be larger than the actual features in the mask. The other main difference between contact and projection photolithography is due to physics. Projection photolithography can be used with a lens system 810 to produce features with very small dimension, but the effectiveness of projection photolithography is limited by the diffraction of light through the lens assembly 810.

The present invention provides low resolution and high resolution contact masks that are inexpensive to produce (e.g., pennies). Any of the aforementioned PDMS-based structures which have the patterned materials on or in the PDMS substrate may be used as a photolithographic mask. In such embodiments, the only requirement is that that patterned material be optically opaque. Some materials that may be used for the photolithographic masks include graphite, zinc oxide, and gold.

Referring again to FIGS. 5-7, in one specific embodiment, photolithographic mask may be manufactured by fabricating two identical optically opaque patterns in two identical PDMS substrates. The optically opaque patterns may be deposited onto the PDMS substrate using any of the above described methods. For example, the first PDMS substrate may be fabricated using the steps of FIG. 5 (steps 500-512). For the second PDMS substrate, instead of depositing a thick layer of liquid PDMS onto the powder pattern at step 510, a thin layer of liquid PDMS may be spun onto the second powder pattern (not shown), which may then be compressed beneath the first cured PDMS layer with the first powder pattern to produce an optically opaque structure than can then be used as a contact lithography mask.

Of course, in other embodiments, the photolithographic masks of the present invention may be comprised of only a single layer of optically opaque material that is fully or partially encapsulated in the PDMS substrate.

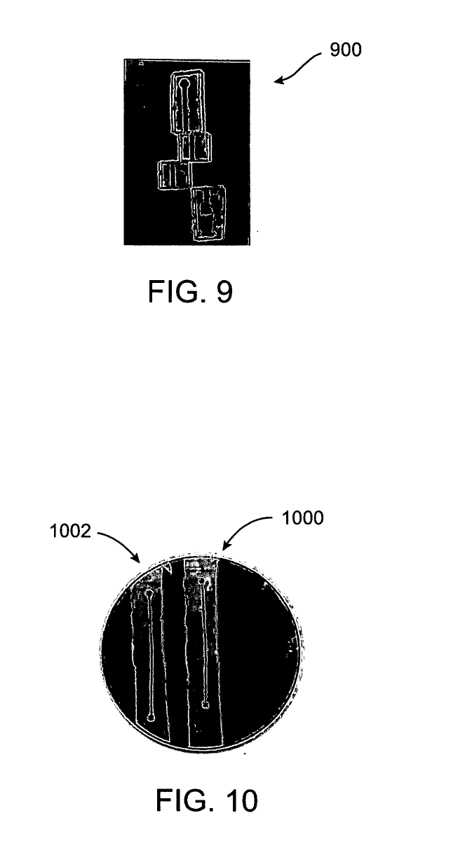

In another method of fabricating a photolithographic mask, an optically opaque powder (e.g., graphite or zinc oxide) can be mixed into a bulk liquid PDMS. The filled, optically opaque liquid PDMS may then be deposited into a channels that is fabricated in a clear PDMS substrate. Curing of the optically opaque PDMS in the channel produces an optically opaque structure than can then be used as a contact lithography mask. FIG. 9 shows a photolithographic mask 900 of the present invention that has a 500 micron wide line pattern formed in a clear PDMS substrate. The channel is filled with a cured, graphite doped PDMS to produce the photolithographic mask of the present invention.

Advantageously, the photolithographic masks of the present invention may be separable and movable so as to provide the ability to produce customized larger or smaller photolithographic mask. For example, the photolithographic mask 900 of FIG. 9 may be sectioned (e.g., with a cutting element such as a razor blade) and realigned and assembled into different shapes. The graphite doped areas of the mask may seal optically with each other merely by pressing the edges of the separate sections together. FIG. 10 illustrates two photoresist structures 1000, 1002 made using a reassembled mask of FIG. 9

In another aspect, the present invention provides multi-layered devices and methods of fabricating the multi-layered devices. A variety of different multi-layered devices can be manufactured, including, but not limited to, hybrid electronic devices and microfluidic devices. The multi-layered devices produced by the present invention may be fabricated using two methods. In one method, the device is built up layer-by-layer on a substrate. In such a method, the resultant device can be very thin. In a second method, each individual layer is fabricated, and each of the individual layers are then attached to each other. Such a method provides a versatile manufacturing method that is amenable to large scale manufacturing using sheets of completed layers. Of course, in some embodiments, it may be possible to build a portion of the device layer-by-layer, and then add one or more individually fabricated layers to the device.

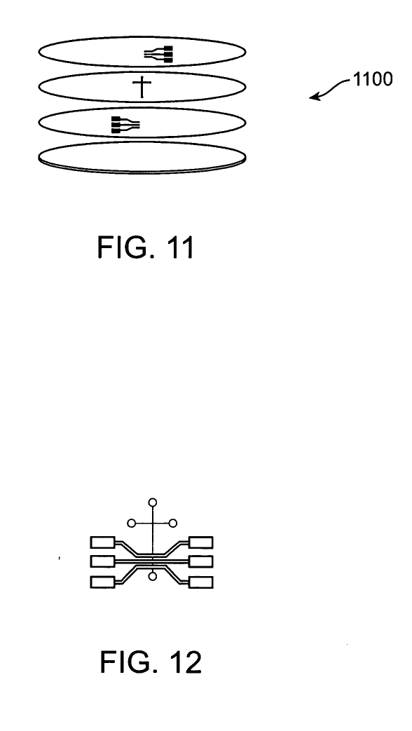

One multi-layered device encompassed by the present invention is an electrostatically actuated peristaltic pump, as shown in FIGS. 11 and 12. FIG. 11 is an exploded view of a five layer buildup 1100, in which each of the layers may be fabricated using any of the methods described herein. As noted above, each of the layers may be fabricated individually or each layer may be built up on top of the previous layer. FIG. 12 is a photo of the cured five layer buildup device of FIG. 11. Of course, the structures of the present invention may include any number of layers.

The fabrication methods for multi-layer devices result in electrodes/leads/wires/conductive structures that are embedded between multiple layers of PDMS. Consequently, the conductive structures are often electrically inaccessible and modifications to the multi-layered device may be needed in order to make electrical contact with the embedded conductive structures.

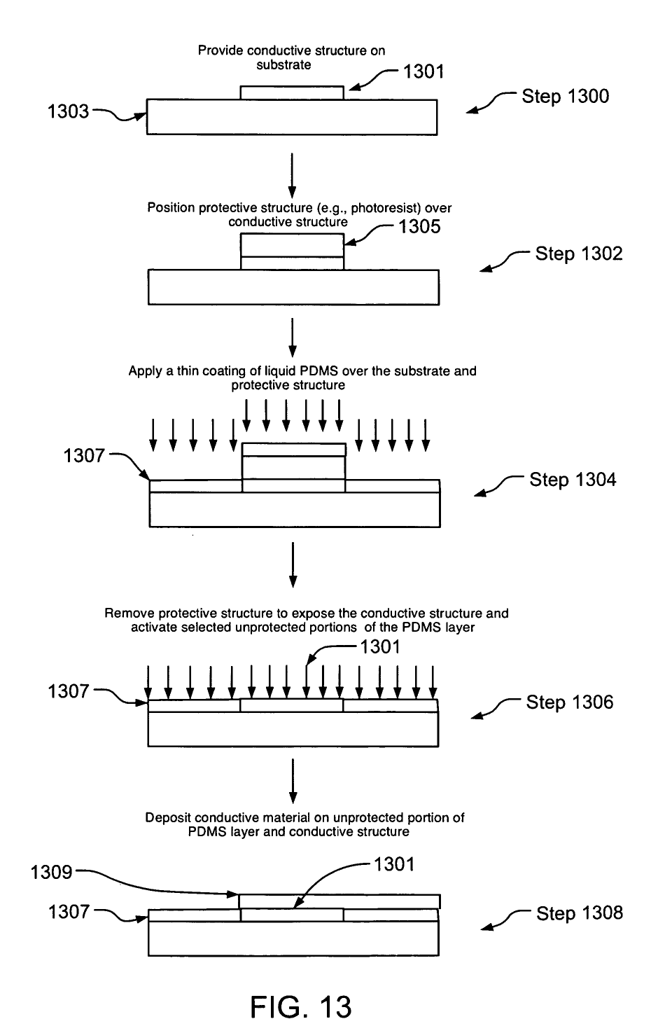

FIG. 13 schematically illustrates one method of making electrical contact with the embedded conductive structure 1301 (e.g., gold lead/gold electrode). In this method, a conductive structure 1301 is deposited on a glass, silicon, PDMS, or other substrate 1303 using conventional or proprietary methods (Step 1300). A thick layer of photoresist or another protective layer 1305 is placed over the conductive structure (Step 1302) and PDMS 1307 is spun onto the substrate in a thin layer that does not completely cover the protective structure (e.g., photoresist) (Step 1304). The protective structure is removed from the surface of the conductive structure. The resultant configuration is a conductive structure 1301 that is surrounded/embedded in a layer of PDMS 1307. From this point, the methods described above (e.g., FIG. 1, 3, or 4) may be used to pattern a conductive material 1309 over the PDMS and the conductive structure 1301 so as to make electrical contact with the embedded conductive structure. While not shown in FIG. 13, a patterned protective structure may be placed over the PDMS layer to form the pattern for the conductive material. Thereafter, the unprotected portion of the PDMS layer may then be activated (Step 1306). After activation, the protective structure may be removed (not shown) and a conductive material (e.g., gold) 1309 may be self assembled or otherwise deposited onto the PDMS layer and the embedded conductive structure to make an electrical connection to other electronic components (Step 1308).

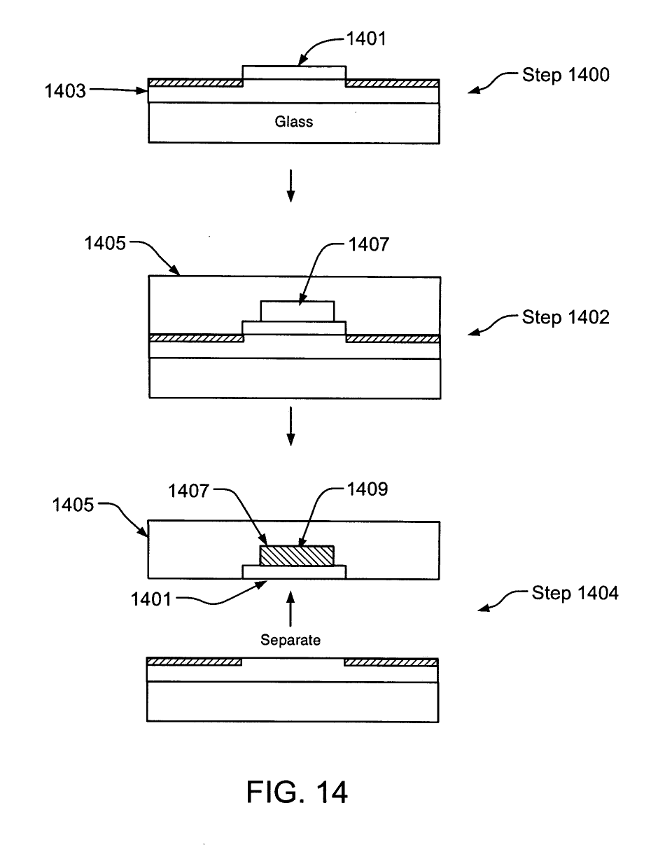

FIG. 14 shows another method of making electrical contact with embedded conductive structure 1401 that is disposed on or in a PDMS substrate 1403. As shown in FIG. 14, a conductive structure 1401 may be deposited on a PDMS substrate 1403 using the aforementioned methods (Step 1400). While not shown in the figures, n some embodiments, instead of using a powder as the electrode, it may be possible to fabricate the electrode using a conductively doped PDMS.

A preformed PDMS structure 1405 that comprises a channel 1407 may be coupled to a surface of the PDMS layer so that an open end of the channel is adjacent a top surface and overlapping of the conductive structure deposited on the PDMS substrate 1403 (Step 1402). The PDMS structure 1405 may be cured and bonded to the PDMS substrate 1403 to complete the encapsulation of the conductive structure 1401. Alternatively, if the PDMS substrate 1403 was first treated with silane, the conductive structure 1401 may optionally be lifted off of the PDMS substrate 1403 altogether (Step 1404).

In either embodiment, it is possible to create access to the conductive structure embedded in the PDMS structure 1401 coring holes (not shown) into the completed structure at the ends of the channels 1407 over the conductive structure and a silver paint (or another conductive fluid 1409) is then allowed to wick or is otherwise be injected into the channel 1407 so as to contact and make an electrical connection with the encapsulated conductive structure 1401. Such a method enables connections to external electronics via the silver paint or conductive fluid.

### EXAMPLES

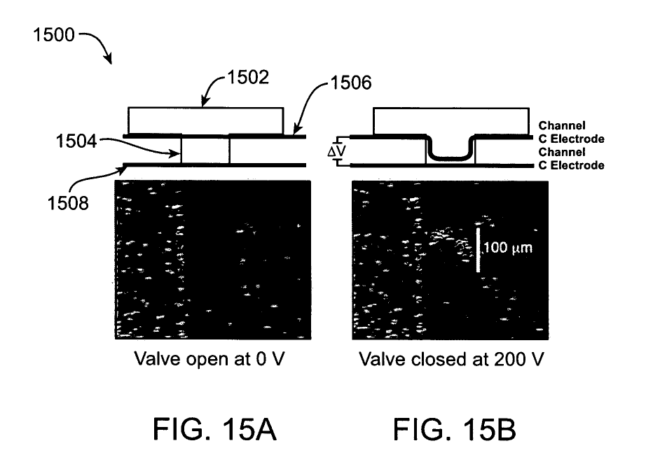

FIGS. 15A and 15B illustrate one exemplary electrostatic valve or actuator formed in a PDMS substrate that may be manufactured by the methods of the present invention. The valve illustrated in FIGS. 15A and 15B are manufactured by stacking a plurality (e.g., two or more, and preferably about seven layers) of PDMS, in which at least some of the layers contain components that have conductive leads and/or electrodes. For ease of reference, the seven layers are not shown, and only the pertinent features of the valve are illustrated in FIGS. 15A and 15B.

As shown in FIG. 15A, the valve 1500 comprises a first and second crossed channels 1502, 1504. The first and second channels 1502, 1504 are separated by a first flexible electrode/plate/membrane 1506. A second electrode/plate/membrane 1508 is positioned on an opposed side of second channel 1504. As shown, the first channel 1502 has a larger width than the second channel. Pressure created by the electrodes is proportional to the voltage, and inversely proportional to the distance between the electrodes. Thus, it is preferred that the electrodes be as close as possible to each other. Typically, the electrodes are approximately 10 microns apart, but in preferred embodiments, the electrodes are less than 10 microns apart. When no voltage is applied to the first electrode 1506 and the second electrode 1508, fluid is allowed to flow through the second channel.

As shown in FIG. 15B, application of a voltage between flexible, first electrode 1506 and the second electrode 1508 (typically between about 100 Volts and about 600 Volts, and preferably about 200 Volts), caused the flexible first electrode to flex or otherwise bow into the second channel 1504 to reduce (e.g., stop) fluid flow through the second channel 1504. Flexing of the first electrode 1506 is caused from the electrostatic attraction between the two charged electrodes.

One difficulty associated with the operation of the valve 1500 is that while conventional fabrication of gold leaf electrodes via evaporation onto elastomer is possible, Applicant has found that such gold leaf electrodes are quite fragile and are not able to withstand the two dimensional stretching that occurs when the first electrode flexes into the second channel 1504. Applicant has found that the flexing of such gold leaf electrodes produces considerable stress and that such electrodes often shatter on its first use due to the two-dimensional stretching.

To overcome such stresses, the valves and pumps of the present invention often comprise an extensible carbon powder (e.g., graphite) that is embedded in a PDMS membrane. Because the carbon powder granules are able to move relative to each other during the two-dimensional stretching, while still being able to maintain electrical contact with each other, Applicant has found that such electrodes are flexible and stretchable and have not demonstrated mechanical failure.

Yet another preferred electrode configuration that may be used with the valve 1500 of FIGS. 15A and 15B is a composite of gold and graphite powder. In such embodiments, the liquid gold is allowed to intercalate between the graphite granules. Such electrodes provide the flexibility of the graphite powder while providing the conductivity of a gold electrode.

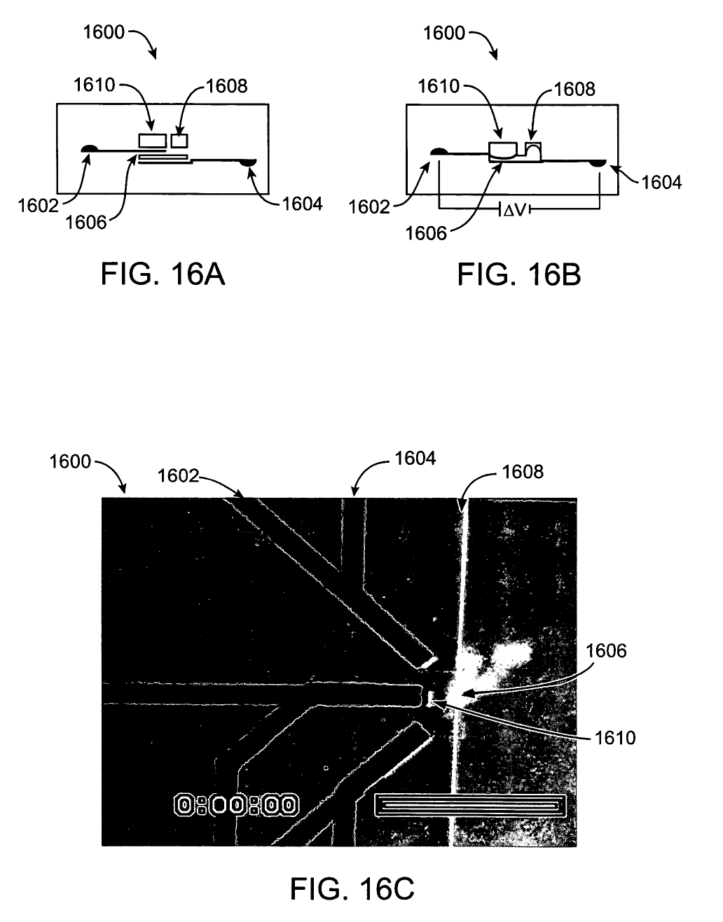

FIG. 16A to 16C illustrate an exemplary electrostatic actuator or pump 1600 that is encompassed by the present invention. Similar to the valve of FIGS. 15A and 15B, the pump 1600 may be formed by combining a plurality of PDMS-based layers manufactured by the aforementioned methods, in which at least some of the layers contain components that have conductive leads and/or electrodes.

The pump 1600 comprises a first and second electrode 1602, 1604 (e.g., an actuator electrode and a ground electrode) disposed in a parallel offset orientation. A portion of each of the electrodes “overlap” each other, so that upon application of a voltage, the electrostatic attraction between the first and second electrode causes the first electrode 1602 to flex or bow toward the second electrode 1604. The first and second electrodes are positioned on opposed sides of a first channel 1606 (e.g., working fluid channel). The working fluid channel 1606 will contain a working fluid. The working fluid can be a number of different fluids (e.g., air, silicone oil, propylene glycol, ethylene glycol), but the working fluid should ideally be an insulator that has a dielectric constant higher than that of air and have low viscocity so as to reduce the voltage required to produce a given pressure between the electrodes/plates (or conversely to increase the pressure for a given voltage). The working fluid channel is bounded by a PDMS membrane along each of its sides. As can be appreciated, higher viscosity fluids may also be used, but such fluids will slow down the intrinsic function of the actuator (e.g., it will be a damping element and also causes a need for an increased energy to actuate)

A second channel (e.g., sample channel) 1608 and a third channel 1610 (void volume) are disposed within the multiple layers of pump 1600 and are typically positioned on an opposite side of the first electrode 1602 from the first channel 1606. The third channel 1610 is positioned so as to allow the extensible first electrode to flex toward the second electrode. It should be noted that the working channel 1606 should not contain a conductive fluid, as the ions in the fluid tends to screen the electrodes from each other and no attraction force will be generated between the electrodes. Thus, it is desirable to have an insulating, high dielectric, incompressible working fluid. Some fluids that have worked in prototypes include silicone oil and ethylene glycol.

In use, the actuator of the present invention does not directly manipulative a fluid by squeezing it. Instead, the architecture of the actuator of FIGS. 16A to 16C provides a series of valves that pressurizes the working fluid in the first channel 1606, which effectively creates a bellows, which then compresses a membrane beneath the second channel 1608 that contains the sample fluid. Specifically, delivery of a voltage across the first and second electrode causes the first electrode to flex toward the second electrode. At least a portion of first channel 1606 may be disposed between the overlapped portion of the first and second electrodes 1602, 1604 such that when the first electrode 1602 flexes into the first channel 1606 toward the second electrode 1604, the first electrode 1602 causes a pressurization of the working fluid in the first channel 1606. As shown in FIG. 16B, the pressurization of the working fluid causes a pressurization of the membrane around the first channel and forces the working fluid membrane into the second channel 1608 (e.g., sample channel). The pressurization of the working fluid membrane causes the second channel 1608 to be closed off.

As shown in FIG. 16A, removal of the voltage between the first and second electrodes 1602, 1604 causes the first electrode 1602 to return to its straight configuration. Consequently, the pressurization of the first channel 1606 and second channel 1608 is removed and the sample fluid is allowed to continue to flow through the second channel 1608. Actuation of the electrodes and pressurization of the various channels work together so as to create a peristaltic pump.

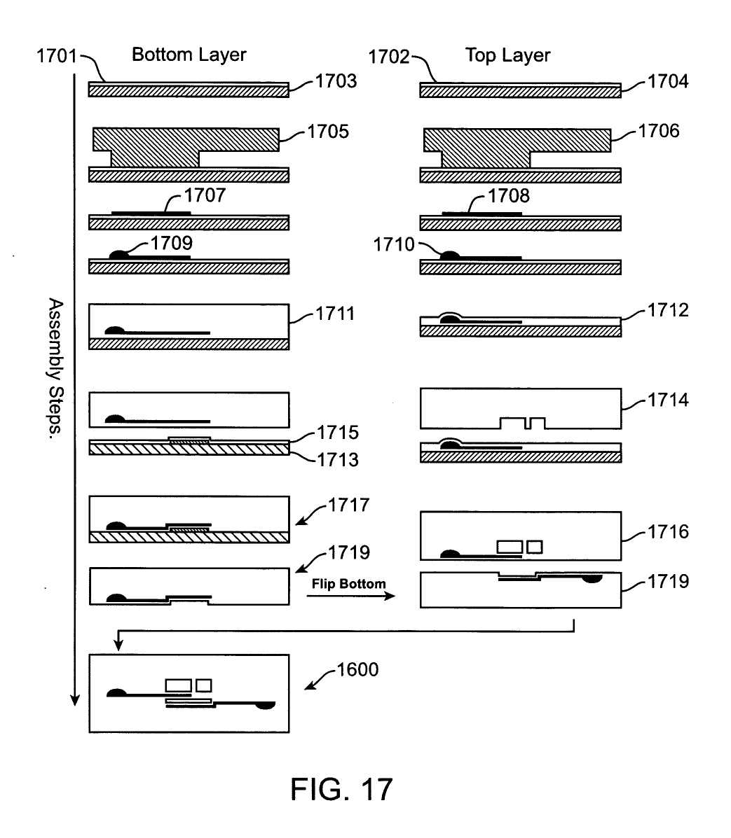

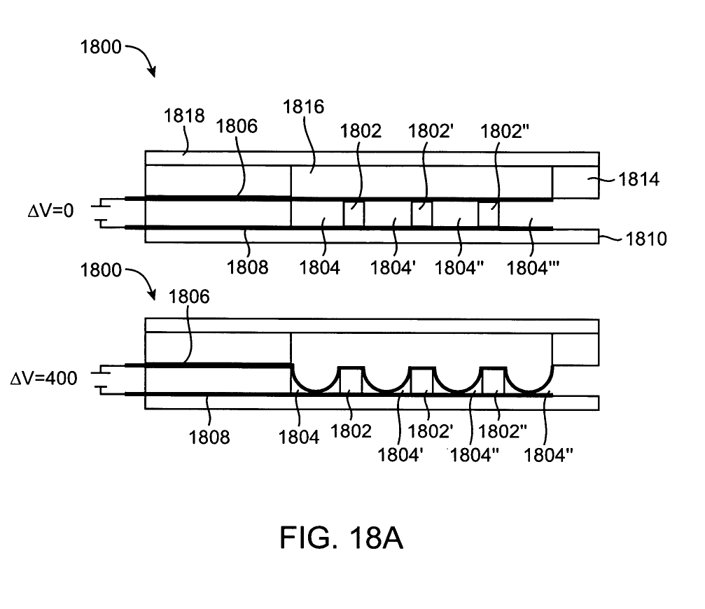

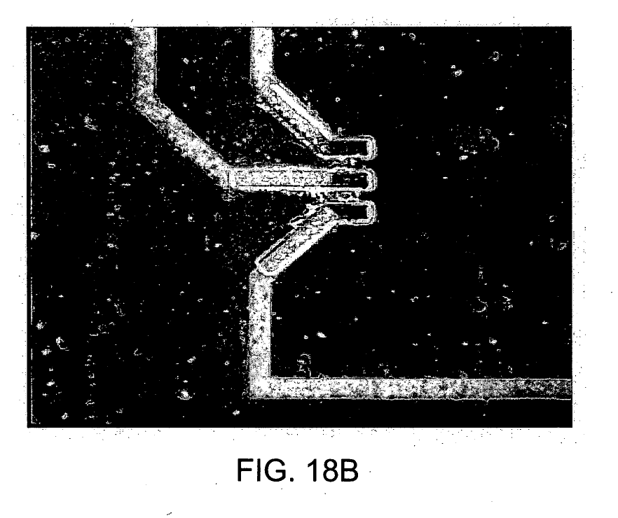

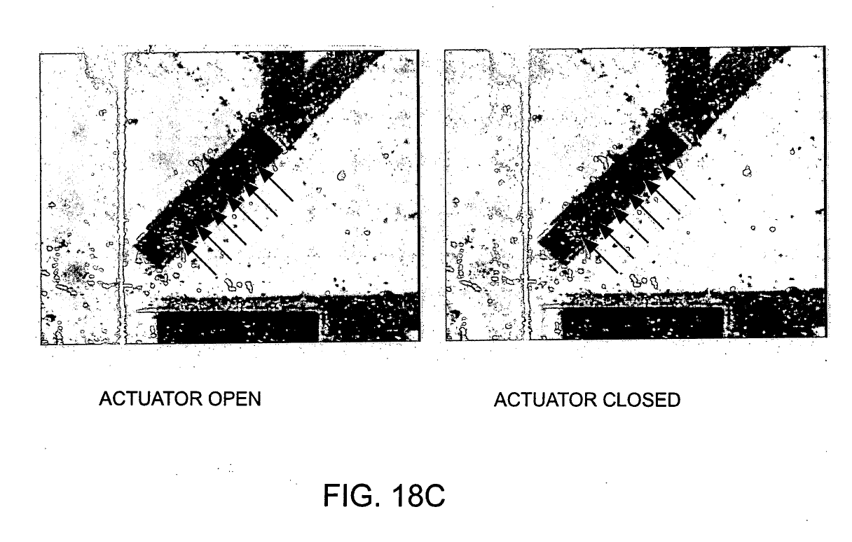

FIG. 17 illustrates one method of fabricating the peristaltic pump 1600 of FIGS. 16A to 16C. The assembly method is divided into top layer (right side) and a bottom layer (left side). For ease of reference, the assembly method will be described by first describing the assembly of the bottom layer, and then describing the assembly of the top layer. It should be appreciated however, that in practice, the top and bottom layer may be manufactured concurrently or in a different order.

A bottom layer is provided, in which a thin PDMS substrate layer 1701 is formed on a glass wafer 1703. A patterned protective structures 1705 is placed on top of the thin PDMS layers 1701 and the non-protected portion of the PDMS layer is activated (e.g., plasma treated).

Per the methods of FIG. 4, water and graphite powder are applied to the surfaces of the PDMS layer 1701, and the graphite only sticks to the protected portions (e.g., where the protective structure 1705 was covering) to form a conductive electrode 1707 (which corresponds to the second electrode 1604 in FIG. 16A). In order to form a three dimensional contact for the electrode, a graphite doped PDMS 1709 may be added to a selected portion of the electrode.

A thick PDMS layer 1711 is added over electrode 1707 to encapsulate the electrode 1707. Thereafter, the PDMS substrate layer 1701 is removed from the glass wafer 1703, and a bottom surface of substrate layer 1701 is placed on top of a photoresist mold 1713 that is covered with a thin layer (e.g., ˜3 microns) of uncured PDMS 1715. The combination 1717 is cured and the photoresist mold is removed.

The resultant bottom layer 1719 is a monolithic structure that has an electrode encapsulated therein. The portion of the photoresist mold that was removed will form an indentation that eventually becomes the working fluid channel (See element 1606 of FIG. 16A).

For the top layer, a thin PDMS substrate layer 1702 is formed on a glass wafer 1704. A patterned protective structures 1706 is placed on top of the thin PDMS layers 1702 and the non-protected portion of the PDMS layer is activated (e.g., plasma treated).

Water and graphite powder are applied to the surfaces of the PDMS layer 1702, and the graphite only sticks to the protected portions (e.g., where the protective structure 1706 was covering) to form a conductive electrode 1708 (which corresponds to the first electrode 1602 in FIG. 16A). In order to form a three dimensional contact for the electrode, graphite doped PDMS 1710 may be added to a selected portion of the electrode.

Instead of placing a thick layer of PDMS over the electrode 1708, a thin layer of PDMS 1712 is spun onto electrode 1708 to encapsulate the electrode. Thereafter, a pre-molded thick PDMS with two channels formed therein is added on top of the spun-on PDMS layer 1712 (The two channels formed therein, will correspond to the sample channel and void volume of FIG. 16A). The combination 1716 is cured to form a monolithic structure. The glass wafer 1704 is removed, and the top layer combination 1716 may then be combined with the bottom layer 1719 (after it is flipped) and the combination may be cured to form an integrated microfluidic structure 1600 that comprises a plurality of fluid channels and electrodes (e.g., an integrated electromechanical circuit).

It is understood that the examples and embodiments described herein are for illustrative purposes only and that various modifications or changes in light thereof will be suggested to persons skilled in the art and are to be included within the spirit and purview of this application and scope of the appended claims. Numerous different combinations are possible, and such combinations are considered to be part of the present invention.

For example, while not described in detail herein, it may be possible to use a substrate that is intrinsically hydrophilic and to treat selected portions of the hydrophilic substrate to make the selected portions hydrophobic. Thereafter, the conductive material may be self assembled onto the hydrophobic portions of the normally hydrophilic substrate.

In yet further embodiments, it may be possible to use an inverted pattern on untreated PDMS as a mask for gold or powder deposition.

In further alternative embodiments, photoresist can be spun onto untreated PDMS substrate, patterned, and the resulting pattern may be used as a deposition mask for powder of gold.

Additionally, instead of the above methods, the whole surface of the substrate can be plasma treated, and a resist may be spun on and patterned to expose the desired areas where material deposition is desired. The plasma treatment is then allowed to age, thus restoring the hydrophobicity and the oxidation state of the catalyst. Material can then be immediately patterned on the surface, or the resist can first be removed

What is claimed is:

1. A method comprising:
providing an hydrophobic substrate;
positioning a protective structure onto a portion of a surface of the hydrophobic substrate;
activating an unprotected portion of the surface to become hydrophilic, wherein the protected portion of the surface of the substrate remains hydrophobic;
removing the protective structure from the surface of the substrate; and
depositing material on the hydrophobic portion to form a structure on the substrate.

2. The method of claim 1 wherein the hydrophobic substrate is an elastomeric substrate.

3. The method of claim 2 wherein the hydrophobic elastomeric substrate comprises PDMS, the PDMS comprising a silicone-based monomer and a catalyst.

4. The method of claim 3 wherein activating the unprotected portion of the surface is carried out by altering an oxidation state of the catalyst.

5. The method of claim 3 wherein the catalyst comprises platinum.

6. The method of claim 5 wherein the material comprises gold, wherein the gold is deposited onto the hydrophobic portion of the PDMS substrate through a self-assembly electroless process that causes the gold to interact with the platinum catalyst.

7. The method of claim 1 wherein the structure comprises a resistance between a sub-ohm and a mega ohm.

8. The method of claim 1 wherein the material comprises a powder.

9. The method of claim 8 wherein depositing material on the hydrophobic portion comprises:
applying the powder onto the protected and unprotected portions of the surface of the substrate; and
applying water to the protected and unprotected surface of the substrate to remove the powder from the hydrophilic portions of the substrate,
wherein the powder remains coupled to the surface at the hydrophobic portions of the substrate.

10. The method of claim 8 comprising:
applying a liquid elastomer substrate over the powder;
curing the liquid elastomer, wherein the elastomer intercalates into the powder; and
removing the cured liquid elastomer and the powder from the hydrophobic portion of the substrate.

11. The method of claim 8 wherein the powder comprises graphite, iron oxide, zinc oxide, semiconductor powders, conductive optically opaque powders, or non-conductive optically opaque-powders.

12. The method of claim 1 wherein the structure formed on the hydrophobic portion comprises wires, inductor cores, resistors, capacitors, electrostatically-actuated valves, pumps, magnetic elements or heaters.

13. The method of claim 1 wherein protective structure comprises a patterned PDMS pad, patterned photoresist, a mylar stencil, metal foil, plastic sheeting, glass mask, or a silicon mask.

14. The method of claim 1 wherein activating the unprotected portion of the surface comprises applying a plasma or acid treatment.

15. The method of claim 1 comprising:
positioning a top layer over the material and the substrate which has a channel formed therein, the channel adapted to be over the material;
creating openings at the ends of the channel; and
filling the channel with a conductive fluid so as to contact the material.

16. A microfluidic structure or hybrid electronic structure formed by the method of claim 1.

17. A method of manufacturing a photolithographic mask, the method comprising:
providing a hydrophobic PDMS substrate;
positioning a patterned protective structure onto a portion of the surface of the hydrophobic PDMS substrate;
activating an unprotected portion of the surface to become hydrophilic, wherein the patterned protected portion of the surface of the PDMS substrate remains hydrophobic;
removing the patterned protective structure from the surface of the PDMS substrate to expose the patterned protected portion; and
depositing an optically opaque material on the patterned hydrophobic portion of the PDMS substrate.

18. The method of claim 17 comprising applying a layer of silane onto the surface of the PDMS substrate prior to activating.

19. The method of claim 18 comprising:
encapsulating the optically opaque material and the silane coated hydrophilic portion of the PDMS substrate with a liquid PDMS; and
curing the liquid PDMS; and
removing the cured liquid PDMS and the patterned optically opaque material from the PDMS substrate.

20. The method of claim 19 wherein encapsulating the optically opaque material is carried out by spinning the liquid PDMS.

21. The method of claim 19 comprising sectioning the cured liquid PDMS and the patterned optically opaque material and rearranging the sections into a different shape.

22. The method of claim 19 wherein the optically opaque material comprises graphite or zinc oxide.

23. A photolithographic mask fabricated by the method of claim 19.

24. A method of manufacturing a photolithographic mask, the method comprising:
providing a substrate that comprises one or more channels;
mixing an opaque powder with a liquid elastomer;
filling the channel(s) with the mixture of optically opaque powder and liquid elastomer;
curing the mixture to form an optically opaque photolithographic pattern in the substrate.

25. The method of claim 24 wherein the substrate and liquid elastomer comprise PDMS.

26. The method of claim 24 wherein the optically opaque powder comprises graphite or zinc oxide.

27. The method of claim 24 comprising sectioning the substrate and optically opaque photolithographic pattern and rearranging the sections into a different shape.

28. A photolithographic mask fabricated by the method of claim 24.

29. A method of manufacturing a multi-layered device, the method comprising:
providing a conductive element disposed within an hydrophobic substrate, the conductive structure and elastomer positioned on a base;
positioning a protective structure onto a portion of a surface of the hydrophobic substrate;
activating an unprotected portion of the surface to become hydrophilic, wherein the protected portion of the surface of the substrate remains hydrophobic;
removing the protective structure from the surface of the substrate; and
depositing conductive material on the hydrophobic portion and on the at least a portion of the conductive element.

30. The method of claim 29 wherein providing the conductive structure disposed within the hydrophobic substrate is carried out by:
depositing a conductive element on the base;
positioning a protective structure over the conductive element;
depositing a liquid elastomer onto the substrate and over the protective structure;
curing the liquid elastomer on the substrate;
removing the protective structure so as to expose the conductive element; and

31. The method of claim 29 wherein the hydrophobic substrate comprises PDMS.

32. The method of claim 31 wherein the conductive element and conductive material comprise gold, wherein the gold conductive material is deposited onto the hydrophobic portion of the hydrophobic substrate through a room temperature, self-assembly electroless process.

33. The method of claim 29 wherein the conductive element comprises gold, copper, graphite, zinc oxide, or iron oxide.

34. A multi-layered device fabricated by the method of claim 29.

35. An electrostatic actuator comprising:
a body comprising a first channel and a second channel;
a flexible, first electrode and a second electrode disposed within the body and separated by a third channel; and
a flexible membrane disposed between the second channel and the third channel, wherein application of a voltage across the first and second electrodes causes the first electrode to flex into the third channel, which pressurizes a fluid within the third channel so as to cause the membrane to extend into the second channel.

36. The actuator of claim 35 wherein the second channel contains a sample fluid and the third channel contains a working fluid.

37. The actuator of claim 35 wherein the body comprises PDMS.

38. The actuator of claim 35 wherein the first electrode comprises a conductive powder.

39. The actuator of claim 35 wherein the first electrode further comprises gold intercalated in the graphite powder.

40. The actuator of claim 35 wherein the voltage is between about 50 Volts and about 600 Volts.
